(19) United States
(12) Patent Application Publication
(10) Pub. No.: US 2009/0287362 A1
(43) Pub. Date: Nov. 19, 2009

(54) MONITORED BURN-IN TEST APPARATUS AND MONITORED BURN-IN TEST METHOD

(75) Inventors: Yoshihiro MAESAKI, Kawasaki (JP); Hiroshi TESHIGAWARA, Kawasaki (JP); Yukihiko KODAIRA, Kawasaki (JP); Naoe SEKIGUCHI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/533,504

(22) Filed: Jul. 31, 2009

Related U.S. Application Data
(63) Continuation of application No. PCT/JP2008/051581, filed on Jan. 31, 2008.

(30) Foreign Application Priority Data
Feb. 1, 2007 (JP) 2007-023319
Feb. 6, 2007 (JP) 2007-026584
Mar. 20, 2007 (JP) 2007-073432

(51) Int. Cl. G05D 23/19; G11C 29/00; G11C 7/00

(52) U.S. Cl. 700/300; 365/201; 365/222

(57) ABSTRACT

A monitored burn-in test method includes: subjecting an element set, including elements, to a writing process for writing data into each of the elements, the elements requiring a refresh process; subjecting the element set to the refresh process after the writing process; and interrupting the refresh process for a selected one or ones of the elements, when instructions for readout of data are supplied to the selected one or ones during the refresh process, and subjecting the selected one or ones to a readout process in accordance with the instructions.

### CROSS-REFERENCE TO RELATED APPLICATION

This application is a continuing application, filed under 35 U.S.C. §111(a), of International Application PCT/JP2008/051581, filed on Jan. 31, 2008, the contents of which are incorporated herein by reference. International Application PCT/JP2008/051581 is based upon and claims the benefit of priority from the prior Japanese Patent Application No. 2007-023319, filed on Feb. 1, 2007, Japanese Patent Application No. 2007-026584, filed on Feb. 6, 2007, and Japanese Patent Application No. 2007-073432, Mar. 20, 2007, the entire contents of which are also incorporated herein by reference.

### FIELD

The embodiments discussed herein are related to a monitored burn-in test apparatus.

### BACKGROUND

A so-called monitored burn-in test is performed prior to shipment of semiconductor devices such as static random access memories (SRAM), for example. A plurality of semiconductor devices as test objects to be subjected to the monitored burn-in test are set on a burn-in board. The semiconductor devices are heated by heaters, for example. The temperatures of the semiconductor devices are kept high such as at 100 degrees Celsius, for example. Simultaneously, the semiconductor devices are driven to operate. Voltage of a level higher than usual is applied to the semiconductor devices. The operation of the semiconductor devices is monitored in this condition.

The monitored burn-in test includes (1) a writing/reading stage, (2) a burn-in stage and (3) a reading stage. (1) The writing/reading stage is first performed. A data writing process and a data reading process are conducted. The written data and the read data are compared with each other. Next, (2) the burn-in stage is performed. A data writing process is continued for a long period of time. Subsequently, (3) the reading stage is performed. The writing process and the readout process are performed. The written data and the read data are compared with each other in the same manner as in the writing/reading stage.

Memories such as a synchronous dynamic random access memory (SDRAM) and a dynamic random access memory (DRAM) require a refresh process, for example. In the case where such memories are subjected to a monitored burn-in test, a time duration from writing operation of data to reading operation of data in the excess of a so-called refresh cycle causes the written data to be lost. Accordingly, the writing process and the readout process are continuously performed to each memory. It takes a considerably long time to apply the writing process and the readout process to all the memories. It is thus quite troublesome to perform the monitored burn-in test on the memories requiring the refresh process.

The monitored burn-in test is performed on all the semiconductor devices of the same type en bloc. All the semiconductor devices need to be kept at a uniform temperature. Temperature sensors are attached to the semiconductor devices one by one for controlling the temperature. Temperature measuring units are connected to the temperature sensors one by one. The temperature measuring units determine the temperatures measured by the temperature sensors, respectively. A controller circuit refers to the determined temperatures to control the temperatures of the heaters. A monitored temperature testing apparatus of this type requires the same number of the temperature measuring units as that of the temperature sensors. This results in an increase in the production cost of the monitored temperature testing apparatus.

The heaters are utilized to heat the test objects. The individual heater includes a cylindrical metallic tube, for example, as disclosed in Japanese Patent No. 3425825, for example. A heat-generating object is inserted in the metallic tube. The bottom surface of the metallic tube is urged against the test object so that the test object is heated. However, the bottom surface of the metallic tube is designed to have a predetermined area. If the test object, which receives the bottom surface of the metallic tube, has a large size, the bottom surface of the heater cannot contact with the test object over a sufficient area, for example. The heater lacks versatility.

### Patent Publication 1: JP Patent Application Laid-open No. 5-36793

### Patent Publication 2: JP Patent Application Laid-open No. 2005-156172

### Patent Publication 3: JP Patent Application Laid-open No. 2005-252225

### Patent Publication 4: JP Patent Application Laid-open No. 10-320974

### Patent Publication 5: JP Patent No. 3425825

### Patent Publication 6: JP Patent Application Laid-open No. 2001-167600

### Patent Publication 7: JP Patent Application Laid-open No. 4-17349

### Patent Publication 8: JP Patent Application Laid-open No. 2001-184896

### SUMMARY

According to an aspect of the present invention, there is provided a monitored burn-in test method comprising: subjecting an element set, including elements, to a writing process for writing data into each of the elements, the elements requiring a refresh process; subjecting the element set to the refresh process after the writing process; and interrupting the refresh process for a selected one or ones of the elements, when instructions for readout of data are supplied to the selected one or ones during the refresh process, and subjecting the selected one or ones to a readout process in accordance with the instructions.

The object and advantages of the embodiments will be realized and attained by means of the elements and combinations particularly pointed out in the appended claims. It is to be understood that both the foregoing general description and the following detailed description are exemplary and explanatory and are not restrictive of the embodiments, as claimed.

### BRIEF DESCRIPTION OF THE DRAWINGS

FIG. 1 is a perspective view schematically depicting a monitored burn-in test apparatus according to an embodiment of the present invention;

FIG. 2 is an enlarged sectional view schematically depicting a burn-in board and a monitored temperature test apparatus;

FIG. 3 is an enlarged partial plan view schematically depicting a monitored temperature test apparatus according to a specific example of the present invention;

FIG. 4 is a sectional view taken along the line 4-4 in FIG. 3;

FIG. 5 is an enlarged partial plan view schematically depicting the monitored temperature test apparatus;

FIG. 6 is an enlarged sectional view schematically depicting a heater;

FIG. 7 is a block diagram schematically depicting a control system of the monitored burn-in test apparatus;

FIG. 8 is a view depicting a writing command;

FIG. 9 is a view depicting a readout command;

FIG. 10 is a view depicting a refresh command;

FIG. 11 a view depicting a refresh cancellation command;

FIG. 12 is a graph schematically depicting the stages of a monitored burn-in test;

FIG. 13 is a flow chart schematically depicting the flow of the monitored burn-in test;

FIG. 14 is a view depicting that a writing process is applied to all the elements;

FIG. 15 is a view depicting that a refresh process is applied to all the elements;

FIG. 16 is a view depicting that a readout process is applied to element set 1 while the refresh process is applied to element sets 2-10;

FIG. 17 is a view depicting that the readout process is applied to element set 2 while the refresh process is applied to element sets 1 and 3-10;

FIG. 18 is a view depicting that the readout process is applied to one of the element sets while the refresh process is applied to the other element sets;

FIG. 19 is a block diagram schematically depicting a control system of the monitored temperature test apparatus according to a specific example of the present invention;

FIG. 20 is a block diagram schematically depicting a control system of the monitored temperature test apparatus according to another specific example of the present invention;

FIG. 21 is an enlarged partial sectional view schematically depicting a heating jig;

FIG. 22 is a perspective view schematically depicting the heating jig;

FIG. 23 is a perspective view schematically depicting the heating jig;

FIG. 24 is a perspective view schematically depicting the heating jig;

FIG. 25 is a side view schematically depicting that the heating jig contacts with the element at a first contact surface;

FIG. 26 is a side view schematically depicting that the heating jig contacts with the element at a second contact surface; and

FIG. 27 is a side view schematically depicting that the heating jig contacts with the element at a third contact surface.

### DESCRIPTION OF EMBODIMENTS

Description will be made below on the embodiment of the present invention with reference to the attached drawings.

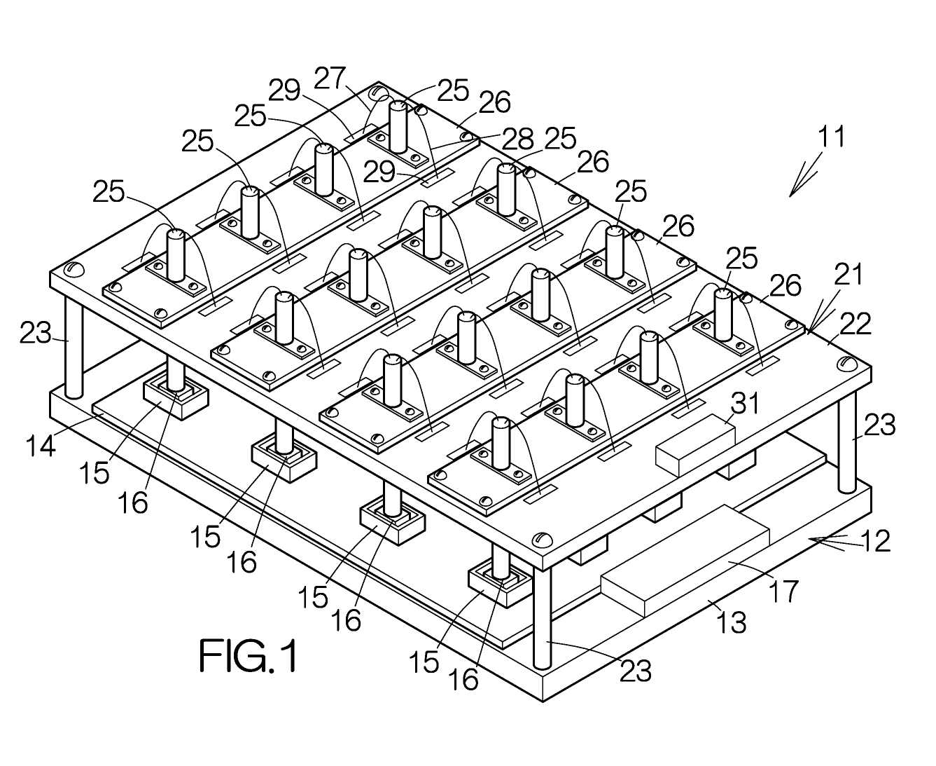

FIG. 1 schematically depicts a monitored burn-in test apparatus 11 according to an embodiment. The monitored burn-in test apparatus 11 includes a burn-in board 12. The burn-in board 12 includes a board body 13 made of resin, for example. A printed wiring board 14 is fixed on the board body 13. The contour of the printed wiring board 14 is defined inside the contour of the board body 13. Sockets 15 are mounted on the surface of the printed wiring board 14. The sockets 15 are arranged in four rows and four columns, for example.

Elements 16 as test objects, to be subjected to a monitored burn-in test, are set in the sockets 15, respectively. All the elements 16 are semiconductor devices of the same type. The elements 16 include memory chips, such as synchronous dynamic random access memory (SDRAM) chips, for example. Such memory chips require a refresh process, for example. A connector 17 is mounted on the board body 13 at a position off the printed wiring board 14. The elements 16 are connected to the connector 17 via wiring patterns, not depicted, formed on the printed wiring board 14. The connector 17 is connected to a controller circuit for a monitored burn-in test, which will be described later.

A monitored temperature test apparatus 21 is located above the burn-in board 12. The monitored temperature test apparatus 21 includes a substrate 22 made of resin, for example. The contour of the substrate 22 is identical to that of the board body 13 of the burn-in board 12. Four support posts 23 are located between the substrate 22 and the board body 13. The support posts 23 are located at the four corners of the board body 13. The support posts 23 serve to space the back surface of the substrate 22 from the front surface of the board body 13 at a predetermined interval. The substrate 22 and the board body 13 are coupled to each other with the supports posts 23.

Heaters 25 are supported in the substrate 22, for example. The heaters 25 are arranged in four rows and four columns, for example. The individual heater 25 is formed in the shape of a column, for example. Four parallel fixation plates 26 are fixed to the substrate 22 for supporting the heaters 25. The heaters 25 stand upright from the front and back surfaces of the substrate 22. The heaters 25 are related to the aforementioned sockets 15 one by one. The positions of the heaters 25 on the substrate 22 correspond to and reflect the positions of the sockets 15 on the board body 13, respectively. In this manner, the lower ends of the heaters 25 are received on the elements 16 in the sockets 15, respectively. The structure of the heaters 25 will be described later in detail.

A power supply wiring 27 and a ground wiring 28 are connected to the individual heater 25. The power supply wiring 27 and the ground wiring 28 are connected to electrically-conductive pads 29 on the substrate 22, respectively. The electrically-conductive pads 29 are formed on the substrate 22 at positions off the fixation plate 26. A connector 31 is mounted on the substrate 22. A power supply cable, not depicted, is connected to the connector 31. The power supply cable is connected to a power supply. The electrically-conductive pads 29 are connected to the connector 31 through an electrically-conductive pattern. In this manner, electric power is supplied to the heaters 25.

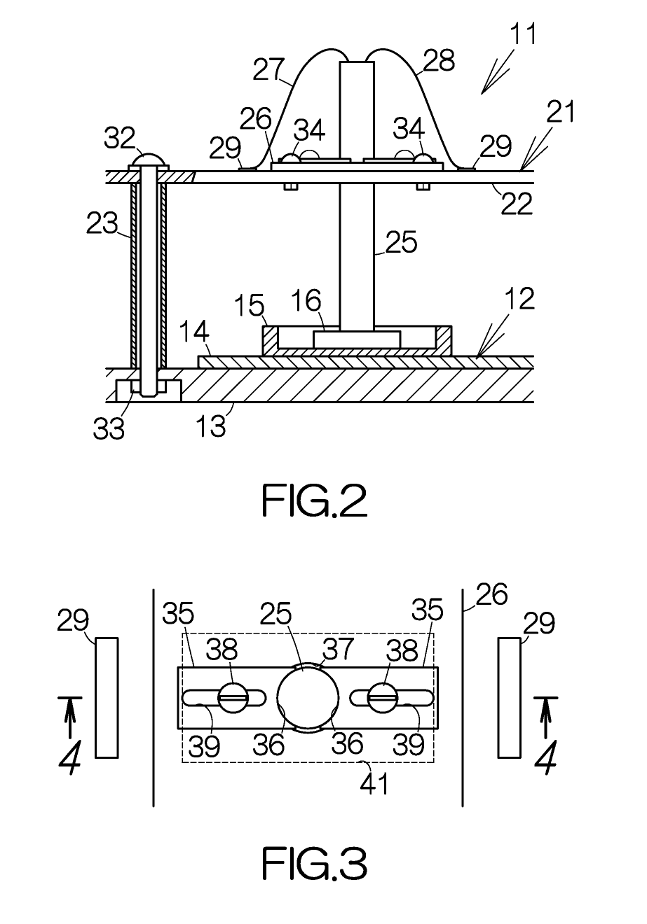

As depicted in FIG. 2, the individual support post 23 is made of a hollow pipe. The interval between the substrate 22 and the board body 13 is adjusted by adjusting the length of the hollow pipe. The screw shaft of a bolt 32 is received in the support post 23. The bolt 32 penetrates through the substrate 22 and the board body 13. The head of the bolt 32 is received on the front surface of the substrate 22. A nut 33 is engaged with the screw shaft of the bolt 32 on the back surface of the board body 13. In this manner, the substrate 22 and the board body 13 are coupled to each other. Screws 34 are utilized to fix the fixation plate 26 to the substrate 22.

As depicted in FIG. 3, pairs of attachment plates 35 are coupled to the fixation plate 26 on the front surface of the fixation plate 26. The individual heater 25 is sandwiched between the inner ends of the attachment plates 35, 35. A recess 36 is defined in the inner end of the individual attachment plate 35. The end surface of the attachment plate 35 along the recess 36 contacts with the outer peripheral surface of the heater 25. The edge of the recess 36 extends along an arc of a predetermined curvature. The radius of curvature of the edge coincides with the radius of the heater 25. In this manner, the attachment plates 35, 35 support the heater 25. The heater 25 is received in a through hole 37 formed in the fixation plate 26. A predetermined gap is formed between the outer peripheral surface of the heater 25 and the wall surface of the through hole 37.

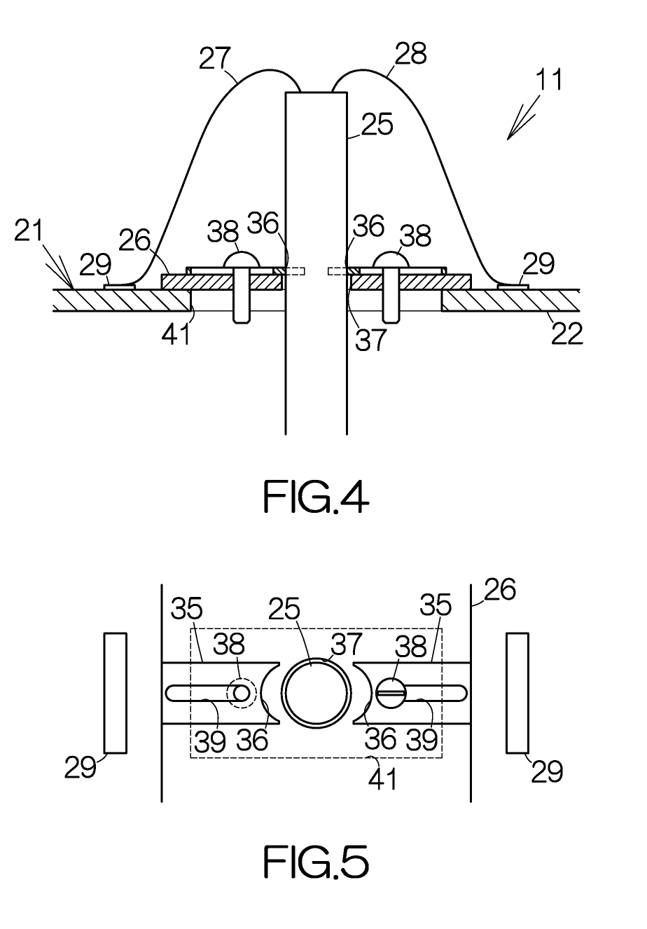

A screw 38 is utilized to couple the individual attachment plate 35 to the fixation plate 26. The screw shaft of the screw 38 is received in a slit 39 formed in the attachment plate 35. The slit 39 extends on an imaginary straight line connecting the electrically-conductive pads 29, 29 to each other. The screw 38 is screwed in the fixation plate 26. Referring also to FIG. 4, the head of the screw 38 is received on the surface of the attachment plate 35. Rectangular openings 41, for example, are formed in the substrate 22. The rectangular openings 41 are assigned to the heaters 25, respectively. The fixation plate 26 closes the openings 41. The heaters 25 and the screw shafts of the screws 38 are received in the openings 41, respectively.

The attachment plates 35 are allowed to slide on the front surface of the fixation plate 26 on the aforementioned imaginary straight line. The combination of the screws 38 and the corresponding slits 39 serves to guide the sliding movement of the attachment plates 35. In this manner, as depicted in FIG. 5, for example, the attachment plates 35 can be positioned at outward positions, which are distanced from the heater 25. Here, the diameter of the through hole 37 of the fixation plate 26 is set larger than that of the heater 25. Therefore, when the attachment plates 35 are positioned at the outward positions, the vertical movement of the heater 35 is accepted in the direction of the longitudinal axis of the heater 25.

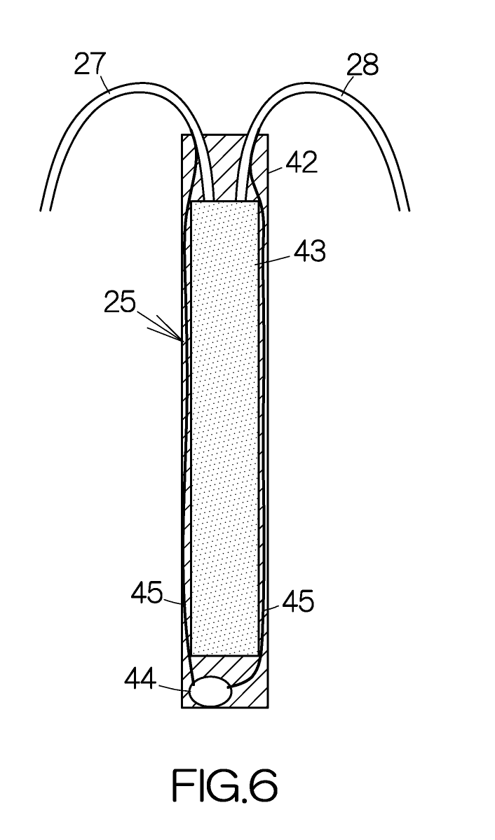

As depicted in FIG. 6, the individual heater 25 includes a cylindrical casing 42. The cylindrical casing 42 may be made of a metallic material such as aluminum, for example. A heat-generating body 43 is located in the cylindrical casing 42. The heat-generating body 43 may be a heating wire, for example. The aforementioned power supply and ground wirings 27, 28 are connected to the heat-generating body 43. The heat-generating body 43 generates heat in response to electric power supplied through the power supply and ground wirings 27, 28. The temperature of the heat-generating body 43 is determined depending on the amount of the electric power supplied to the heat-generating body 43.

A temperature sensor 44 is incorporated in the cylindrical casing 42 of the heater 25. The temperature sensor 44 is located along the bottom plate of the cylindrical casing 42, for example. Wirings 45 are connected to the temperature sensor 44. The wirings 45 are also connected to the substrate 22. The lower end or bottom plate of the cylindrical casing 42 of the heater 25 contacts with the element 16, as described above. The temperature sensor 44 thus detects the temperature of the element 16. The detected temperature is output to the outside from the substrate 22.

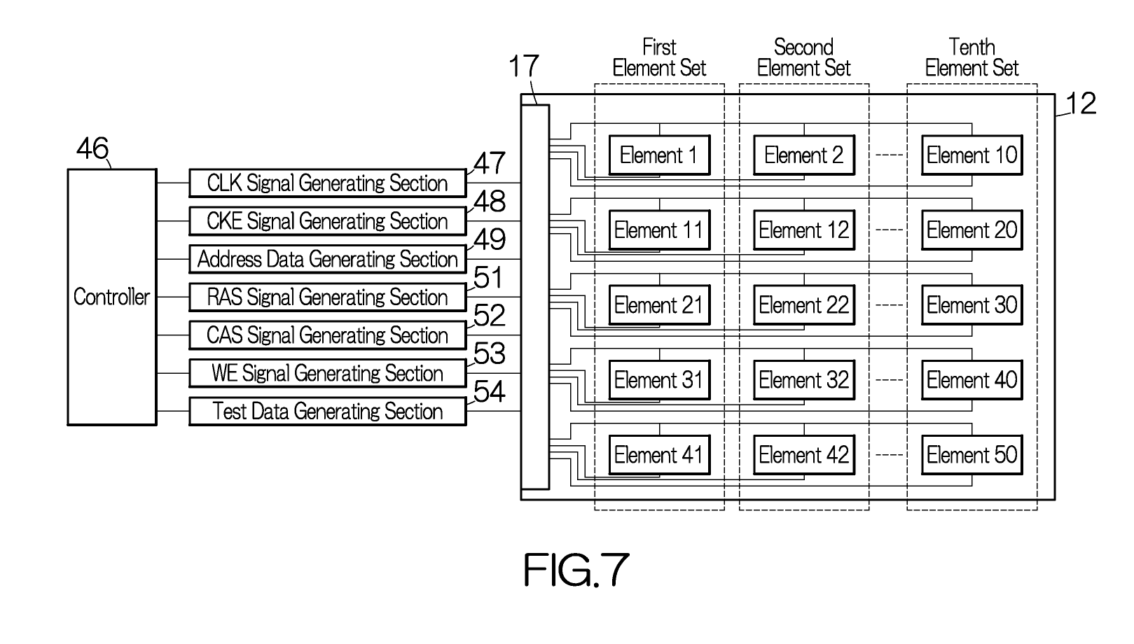

As depicted in FIG. 7, the elements 16, fifty of them, are mounted on the burn-in board 12, for example. The fifty elements 16 are arranged in five rows and ten columns, for example. The elements 16 are set in the sockets 15 on the burn-in board 12, respectively. The elements 16 are SDRAMs. Here, the individual elements 16 are labeled with identifiers from “Element 1” to “Element 50”. One element set is established on the burn-in board 12 based on the five elements 16 of each column. Since the fifty elements 16 are located on the burn-in board 12, ten element sets, namely the first to tenth element sets, are established on the burn-in board 12. Each element set contains the five elements 16. Alternatively, it should be noted that one element set may be established based on the ten elements 16 of each row, for example.

A controller circuit, namely a controller 46, is connected to the connector 17 of the burn-in board 12. The controller 46 operates based on a software program held in a flash memory, not depicted, for example. The controller 46 is connected to a CLK signal generating section 47, a CKE signal generating section 48, an address data generating section 49, an RAS signal generating section 51, a CAS signal generating section 52, a WE signal generating section 53 and a test data generating section 54. The controller 46 is configured to control the output of the signals and data generated in the generating sections 47-54.

The CLK (clock) signal generating section 47 generates a CLK signal. The CLK signal represents an operation reference clock. The CKE (clock enable) signal generating section 48 generates a CKE signal. The CKE signal specifies whether or not a refresh process is effected. The fresh process will be described later in detail. The address data generating section 49 generates address data. The address data specifies the address for a cell or cells within the individual element 16. The RAS (row address strobe) signal generating section 51 generates a RAS signal. The CAS (column address strobe) signal generating section 52 generates a CAS signal. The RAS signal and the CAS signal specify a timing for obtaining the address data. A WE (write enable) signal generating section 53 generates a WE signal. The WE signal specifies whether or not a writing process is effected. The test data generating section 54 generates test data.

One common wiring pattern is connected to all the elements 16 of each row on the burn-in board 12. The common wiring pattern is connected to one terminal of the connector 17. The common wiring pattern is connected to a CLK terminal, an address terminal, a RAS terminal, a CAS terminal, a WE terminal and an input/output terminal, which are formed in the individual element 16. In this manner, “Element 1” to “Element 10” of the first row are configured to receive the common CLK signal, address data, RAS signal, CAS signal, WE signal and test data, for example. Likewise, “Element 11” to “Element 20” of the second row, “Element 21” to “Element 30” of the third row, and . . . are configured to receive the common signals and data, respectively.

A distinct wiring pattern is individually connected to the individual element 16 on the burn-in board 12. The distinct wiring pattern is connected to one terminal of the connector 17. The distinct wiring pattern is connected to a CKE terminal formed in the individual element 16. In this manner, a CKE signal is separately input into the individual element 16. In other words, different CKE signals can be input into “Element 1” to “Element 50”, respectively. The controller 46 controls such CKE signals. It should be noted that distinct wiring patterns cannot be formed on the board body 13 for the aforementioned CLK signal, address data, RAS signal, CAS signal, WE signal and test data because the standard regulates the number of the pins in the connector 17.

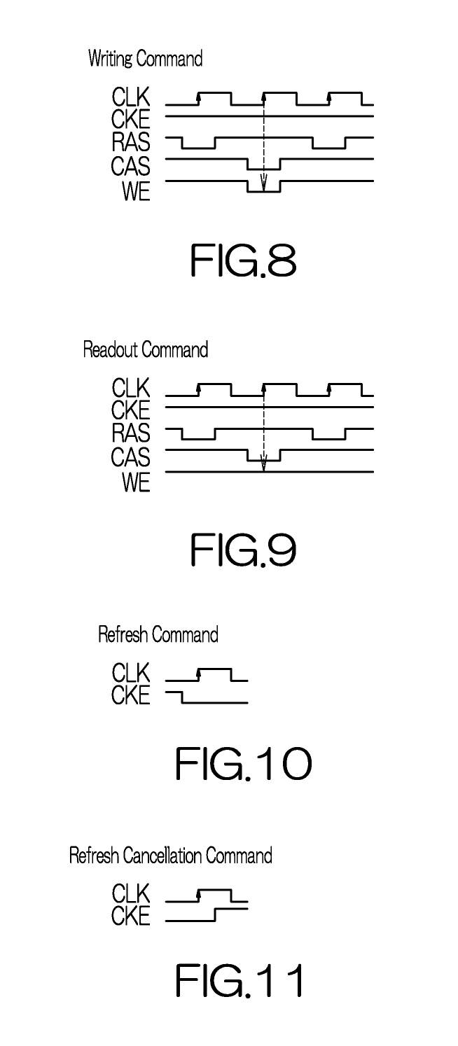

The signals output from the signal generating sections 47-53 under the control of the controller 46 serve to establish various kinds of commands. As depicted in FIG. 8, when the WE signal is set at “0” at the time of the rise of the CLK signal, a writing command is established. As depicted in FIG. 9, when the WE signal is set at “1” at the time of the rise of the CLK signal, a readout command is established. As depicted in FIG. 10, when the CKE signal is set at “0”, a refresh command is established. While the CKE signal is kept at “0”, a self refresh process is continued for a selected one or ones of “Element 1” to “Element 50”. As depicted in FIG. 11, when the CKE signal is set at “1”, a refresh cancellation command is established.

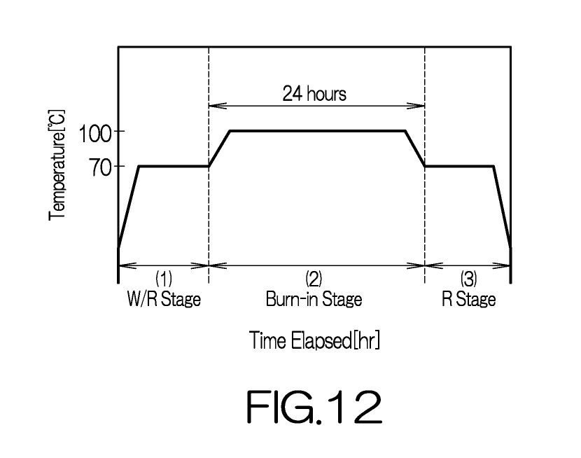

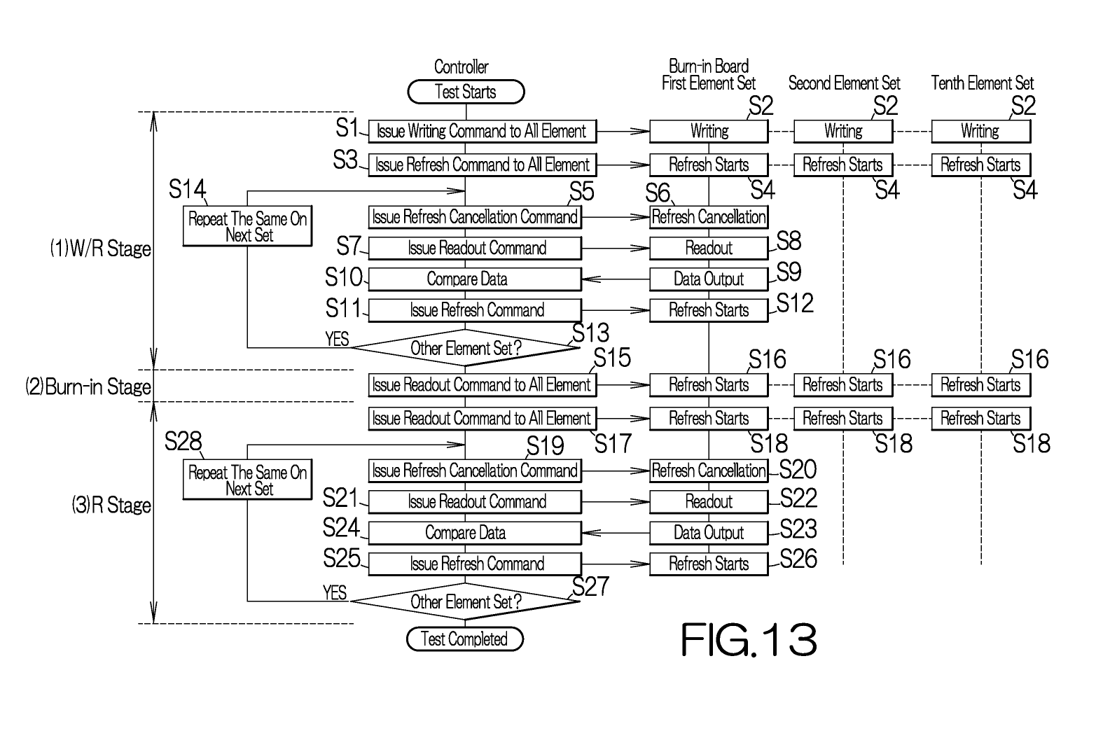

Next, description will be made on a so-called monitored burn-in test. “Element 1” to “Element 50” are set in the sockets 15 of the burn-in board 12, respectively. As depicted in FIG. 12, a writing/reading stage (W/R stage) is first performed. At the writing/reading stage, “Element 1” to “Element 50” are heated in response to the heat generated by the heaters 25. The temperatures of “Element 1” to “Element 50” are kept at 70 degrees Celsius approximately. At step S1 of FIG. 13, the controller 46 establishes a common writing command to “Element 1” to “Element 50” belonging to all the first to tenth element sets. The writing command is broadcast into all of “Element 1” to “Element 50” through the common wiring patterns and the distinct wiring patterns. As a result, test data output from the test data generating section 54 is written into all of “Element 1” to “Element 50” en bloc, as depicted in FIG. 14. “Element 1” to “Element 50” receive the address data at a timing determined by the RAS signal and the CAS signal. In this manner, test data is written into a predetermined cell at step S2.

The controller 46 establishes a common refresh command for all of “Element 1” to “Element 50” at step S3. The refresh command is input into all of “Element 1” to “Element 50” through the common wiring patterns and the distinct wiring patterns. As a result, “Element 1” to “Element 50” start being subjected to a self refresh process at step S4, as depicted in FIG. 15. The self refresh process serves to hold the written test data in “Element 1” to “Element 50”. The controller 46 generates the aforementioned refresh cancellation command at step S5. Since the CKE signal can separately be input into each of “Element 1” to “Element 50” as described above, the CKE signal set at “1” is input only into “Element 1”, “Element 11”, “Element 21”, “Element 31” and “Element 41” of the first element set. As a result, the self refresh process is interrupted for the elements 16 belonging to the first element set.

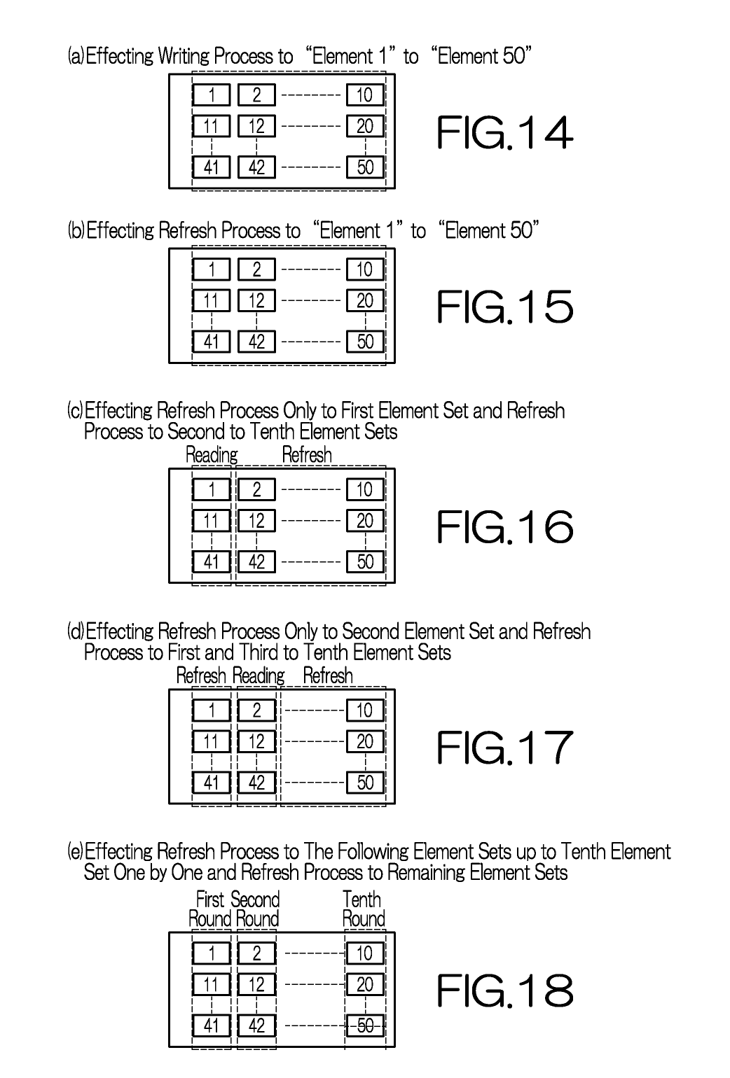

The controller 46 establishes a common readout command for all of “Element 1” to “Element 50” at step S7. The readout command is broadcast into all of “Element 1” to “Element 50” through the common wiring patterns and the distinct wiring patterns. As a result, test data is simultaneously read out from “Element 1”, “Element 11”, “Element 21”, “Element 31” and “Element 41” of the first element set at step S8. As depicted in FIG. 16, since the self refresh process is continued for the second to tenth element sets other than the first element set, the readout command is not input into the second to tenth element sets. Data is output from “Element 1”, “Element 11”, “Element 21”, “Element 31” and “Element 41” at step S9. The controller 46 compares the readout data with the written test data at step S10. The controller 46 determines whether or not the test objects pass the test based on whether or not the readout data coincides with the written test data. The controller 46 then establishes the refresh command for the first element set based on the control of the CKE signal at step S11 in the same manner as described above. The self refresh process is restarted for the elements 16 belonging to the first element set at step S12.

The controller 46 determines whether or not any other element set exists at step S13. Here, since the second to tenth element sets have not been subjected to the readout process, the process proceeds to step S14. The processes of steps S5 to S12 are repeated for the second element set at step S14. As depicted in FIG. 17, data is read out from “Element 2”, “Element 12”, “Element 22”, “Element 32” and “Element 42” after the self refresh process has been interrupted. After comparison of the readout data to the written test data, the self refresh process is restarted for the elements 16 belonging to the second element set. In this manner, as depicted in FIG. 18, the processes of the aforementioned steps S5 to S12 are repeated for each of the third to tenth element sets. Upon completion of the W/R stage for all the element sets, the monitored burn-in test proceeds to a burn-in stage.

At the burn-in stage, as depicted in FIG. 12, the temperatures of “Element 1”, “Element 11”, “Element 21”, “Element 31” and “Element 41” are kept at 100 degrees Celsius approximately by the heaters 25. The controller 46 establishes the common refresh command for “Element 1” to “Element 50” of all the first to tenth element sets again at step S15. The refresh command is input into all of “Element 1” to “Element 50”. As a result, the self refresh process is continued for all of “Element 1” to “Element 50” at step S16. The test data is held in all of “Element 1” to “Element 50”. The self refresh process is continued for 24 hours, for example. In this manner, a so-called dynamic burn-in process is effected. Upon completion of the burn-in stage, the monitored burn-in test proceeds to a readout stage (an R stage).

At the R stage, as depicted in FIG. 12, the temperatures of “Element 1” to “Element 50” are kept at 70 degrees Celsius approximately by the heaters 25. The controller 46 establishes the common refresh command for “Element 1” to “Element 50” of all the first to tenth element sets again at step S17. The refresh command is input into all of “Element 1” to “Element 50”. As a result, the self refresh process is continued for “Element 1” to “Element 50”. The test data is held in all of “Element 1” to “Element 50”. The controller 46 establishes the refresh cancellation command at step S19. The refresh cancellation command is input only into the elements 16 belonging to the first element set based on the control of the CKE signal in the same manner as described above. As a result, the self refresh process is canceled for the element of the first element set at step S20.

The controller 46 establishes the common readout command for all of “Element 1” to “Element 50” at step 21 in the same manner as at the aforementioned W/R stage. The readout command is input into all of “Element 1” to “Element 50”. Data is read from “Element 1”, “Element 11”, “Element 21”, “Element 31” and “Element 41” at step S22. Since the self refresh process is continued for the elements 16 belonging to the second to tenth element sets other than the first element set, the readout command is not input into the elements 16 of the second to tenth element sets. The data is output at step S23. The controller 46 compares the readout data with the written test data at step S23. The controller 46 determines whether or not the test objects pass the test depending on whether or not the readout data coincides with the written test data. The controller 46 then establishes the refresh command for the elements 16 belonging to the first element set at step S24. The self refresh process is restarted for the elements 16 of the first element set at step S25.

The controller 46 determines whether or not any other element set exists at step S27. Here, since the second to tenth element sets have not been subjected to the readout process, the process proceeds to step S28. The processes of steps S19 to S26 are repeated for the second element set at step S28. After the self refresh process has been interrupted, data is read out from “Element 2”, “Element 12”, “Element 22”, “Element 32” and “Element 42” belonging to the second element set in the same manner as described above. After comparison of the readout data with the written test data, the self refresh process is restarted for the elements 16 belonging to the second element set. The processes of the aforementioned steps S19 to S26 are repeated for each of the third to tenth element sets. Upon completion of the R stage for all the element sets, the monitored burn-in test is completed.

In the monitored burn-in test apparatus 11, after the test data is simultaneously written into “Element 1” to “Element 50” en bloc, the self refresh process is effected on all of “Element 1” to “Element 50”. The self refresh process is interrupted only for the elements 16 belonging to a selected one of the element set for the readout process. Upon completion of the readout process, the self refresh process is restarted for the elements 16 belonging to the selected element set. The self refresh process is continued to for the element 16 belonging to the element sets other than the selected element set. As a result, the test data is reliably held in all of “Element 1” to “Element 50”. Since the test data is held, it is not necessary to effect the writing process to “Element 1” to “Element 50” more than once. Therefore, the W/R stage, the burn-in stage and the R stage are performed in series by one monitored burn-in test apparatus 11. The monitored burn-in test can be efficiently performed.

The writing command, the readout command, the refresh command and the refresh cancellation command are established to apply the writing process for the test data, to apply the readout process for the test data, to start the self refresh process, and to cancel the self refresh process, respectively. These commands are generated based on conventional CLK signal, RAS signal, CAS signal and WE signal. Therefore, addition of particular terminals to “Element 1” to “Element 50” is not required. This results in avoidance of a reduction in the access speed to “Element 1” to “Element 50”. The monitored burn-in test can be performed on “Element 1” to “Element 50” of a conventional type. Moreover, a particular circuitry is not required for establishing the commands. The structure of the monitored burn-in test apparatus 11 can be simplified. The versatility of the monitored burn-in test apparatus 11 is improved.

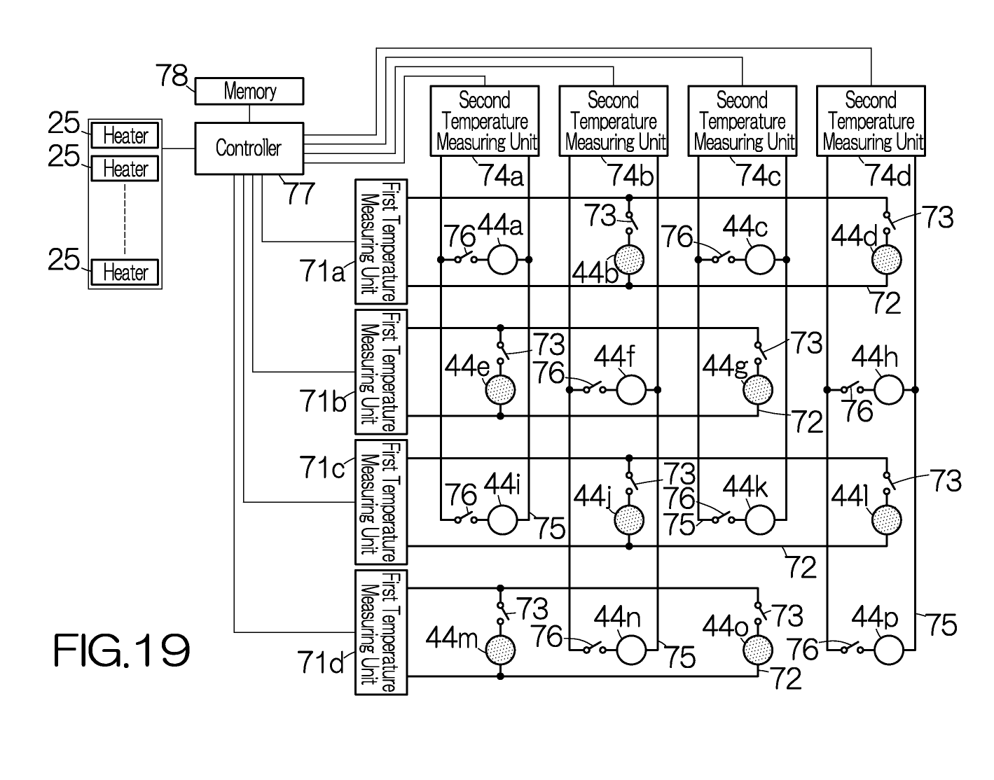

FIG. 19 is a block diagram depicting a control system of the monitored temperature test apparatus 21. As depicted in FIG. 19, the temperature sensors 44a-44p are grouped into a first temperature sensor set and a second temperature sensor set. The first temperature sensor set includes the temperature sensors 44b, 44d, 44e, 44g, 44j, 44l, 44m, 44o. The second temperature sensor set includes 44a, 44c, 44f, 44h, 44i, 44k, 44n, 44p, the remainder of the temperature sensors 44a-44p. The temperature sensors 44 of the first temperature sensor set are selected from the temperature sensors 44 of each row. Likewise, the temperature sensors 44 of the second temperature sensor set are selected from the temperature sensors of each column. The number of the temperature sensors 44 of the first temperature sensor set is common to each row and each column. The temperature sensors 44 of the first and second temperature sensor sets are arranged in each row. The number of the temperature sensors 44 of the first temperature sensor set is equal to the number of the temperature sensors 44 of the second temperature sensor set in each row. The number of the temperature sensors 44 of the first temperature sensor set is equal to the number of the temperature sensors 44 of the second temperature sensor set in each column.

First temperature measuring units 71a-71d are assigned to the rows, respectively. The first temperature measuring units 71a-71d are arranged in this sequence from the first row. The temperature sensors 44b, 44d of the first temperature sensor set are in parallel connected to the first temperature measuring unit 71a, assigned to the first row, through a wiring pattern 72. The wiring pattern 72 is formed on the substrate 22. Switches 73 are inserted in the wiring pattern 72. The switches 73 are assigned to the temperature sensors 44b, 44d, respectively. The temperature sensors 44b, 44d are selectively connected to the first temperature measuring unit 71a through the operation of the switches 73. The first temperature measuring unit 71a detects the temperature of the semiconductor device based on the connected temperature sensors 44.

Likewise, the temperature sensors 44e, 44g of the first temperature sensor set are in parallel connected to the first temperature measuring unit 71b assigned to the second row. The temperature sensors 44j, 44l of the first temperature sensor set are in parallel connected to the first temperature measuring unit 71c assigned to the third row. The temperature sensors 44m, 44o of the first temperature sensor set are in parallel connected to the first temperature measuring unit 71d assigned to the fourth row. The switches 73 are inserted in each of the wiring patterns 72 in the same manner as in the first temperature measuring unit 71a. The switches 73 are assigned to the temperature sensors 44, respectively. The temperature sensors 44 are switched through the operation of the switches 73.

Second temperature measuring units 74a-74d are assigned to the columns, respectively. The second temperature measuring units 74a-74d are arranged in this sequence from the first column. The temperature sensors 44a, 44i of the second temperature sensor set, other than those of the first temperature sensor set, are in parallel connected to the second temperature measuring unit 74a, assigned to the first column, through a wiring pattern 75. The wiring pattern 75 is formed on the substrate 22. Switches 76 are inserted in the wiring pattern 75. The switches 76 are assigned to the temperature sensors 44a, 44i, respectively. The temperature sensors 44a, 44i are selectively connected to the second temperature measuring unit 74a through the operation of the switches 76. The second temperature measuring unit 74a detects the temperature of the semiconductor device based on the connected temperature sensor 44.

Likewise, the temperature sensors 44f, 44n of the second temperature sensor set are in parallel connected to the second temperature measuring unit 74b assigned to the second column. The temperature sensors 44c, 44k of the second temperature sensor set are in parallel connected to the second temperature measuring unit 74c assigned to the third column. The temperature sensors 44h, 44p of the second temperature sensor set are I parallel connected to the second temperature measuring unit 74d assigned to the fourth column. The switches 76 are inserted in each of the wiring patterns 75 in the same manner as in the aforementioned second temperature measuring unit 74a. The switches 76 are assigned to the temperature sensors 44, respectively. The switches 76 are utilized to switch the temperature sensors 44.

A controller circuit, namely a controller 77, is connected to the first temperature measuring units 71a-71d and the second temperature measuring units 74a-74d. The controller 77 is configured to control the operation of the first temperature measuring units 71a-71d, the second temperature measuring units 74a-74d and the heaters 25 in accordance with a predetermined software program. The software program may be held in a memory 78, for example. A monitored temperature test, which will be described later, is performed in accordance with the software program. Data for performing the temperature test may also be held in the memory 78.

The controller 77 notifies the first temperature measuring units 71a-71d of a selected one or ones of the switches 73 for the connection. Likewise, the controller 77 notifies the second temperature measuring units 74a-74d of a selected one or ones of the switches 76 for the connection. The first temperature measuring units 71a-71d and the second temperature measuring units 74a-74d obtains the temperatures of the connected temperature sensors 44. The controller 77 specifies the amount of electric power for each of the heaters 25 in accordance with the detected temperature. The controller 77 may refers to relationships between the amount of electric power and temperature held in the memory 78 for such specification.

Next, description will be made on the operation of the monitored temperature test apparatus 21. The controller 77 executes a predetermined software program. Electric power of a predetermined amount is supplied to the heaters 25 in response to the instructions of the controller 77. The heaters 25 generate heat. The temperatures of the elements 16 rise. Simultaneously, the controller 77 notifies the first temperature measuring units 71a-71d and the second temperature measuring units 74a-74d of a selected one or ones of the switches 73, 76 for the connection. Either one of the switches 73 is connected in each row. Either one of the switches 76 is connected in each column. In this manner, each of the first and second temperature measuring units 71a-71d and 74a-74d is connected to either one of the temperature sensors 44 of the related row and column.

The heat generated by the heaters 25 is utilized to set the temperatures of the elements 16 within a predetermined temperature range. Such a temperature range is set higher than 98 degrees Celsius but lower than 102 degrees Celsius, for example. The connected temperature sensors 44 detect the temperatures of the elements 16, respectively. A measuring process is performed for the first time. The detected temperatures are output to the controller 77. The controller 77 determines whether or not the detected temperatures are out of the predetermined temperature range. If the detected temperature is 102 degrees Celsius or higher, for example, the amount of the electric power supplied to the related heater 25 is reduced. If the detected temperature is 98 degrees Celsius or lower, for example, the amount of the electric power supplied to the related heater 25 is increased.

The switches 73, 76 are switched in each row and each column. The remaining switches 73, 76 are connected. The remaining temperature sensors 44 are connected to the first temperature measuring units 71a-71d and second temperature measuring units 74a-74d, respectively. The connected temperature sensors 44 detect the temperatures of the elements 16, respectively, in the same manner as described above. The measuring process is performed for the second time. The controller 77 determines whether or not the detected temperatures are out of the predetermined temperature range. The amount of the electric power supplied to the related heater 25 is adjusted in accordance with the detected temperature. In this manner, the temperatures of all the elements 16 are kept uniform within the predetermined temperature range.

Electric power is supplied to the elements 16 from a power source via the burn-in board 12. Voltage of a level higher than a usual level is applied to the elements 16. The elements 16 are driven to operate. The operation of the elements 16 is examined. It is checked whether or not defective products exist. The monitored temperature test apparatus 21 is removed from the burn-in board 12. The burn-in test is completed.

In the monitored temperature test apparatus 21, each of the first temperature measuring units 71a-71d can selectively be connected to the temperature sensors 44 of the related row. Likewise, each of the second temperature measuring units 74a-74d can separately be connected to the temperature sensors 44 of the related column. The first temperature measuring units 71 are respectively assigned to the rows and the second temperature measuring units 74 are respectively assigned to the columns for detection of the temperatures of all the elements 16. The number of the temperature measuring units can be significantly reduced as compared with the case where the temperature measuring units are connected to all the temperature sensors 44 one by one. The production cost of the monitored temperature test apparatus 21 is significantly reduced.

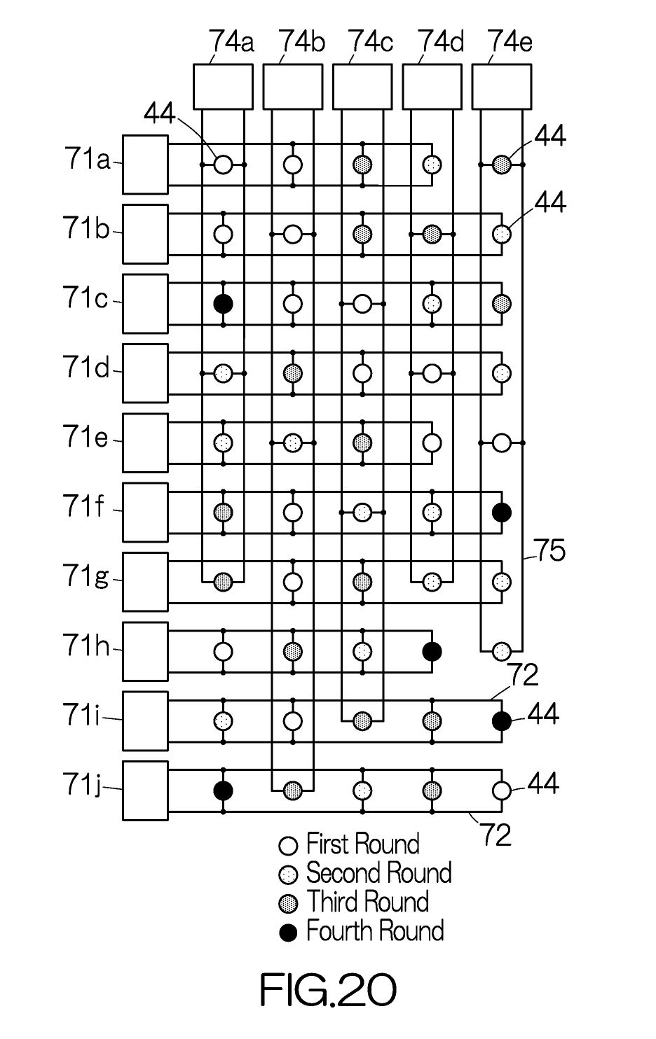

As depicted in FIG. 20, the temperature sensors 44 may be arranged in ten rows and five columns. In this case, the elements 16 are likewise arranged in ten rows and five columns on the burn-in board 12. First temperature measuring units 71e-71j are provided for the added rows, respectively. A second measuring unit 74e are provided for the added column. The switches 72, 75 are inserted in the wiring patterns 72, 75 for the temperature sensors 44, respectively, in the same manner as described above. The switches 73, 76 are configured to identify the temperature sensors 44 for the measurement. In this manner, the temperatures of all the elements 16 can be detected by performing the measurement for four times based on the operation of the switches 73, 76. The number of the temperature measuring units can be reduced in the same manner as described above. The production cost of the monitored temperature test apparatus 21 can be reduced.

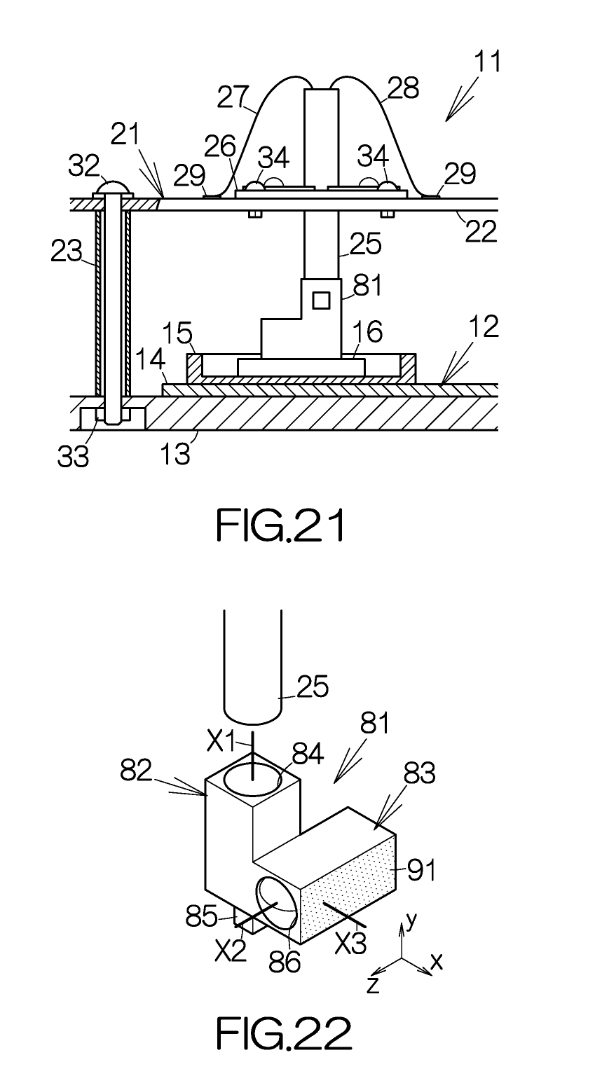

As depicted in FIG. 21, a heating jig 81 may be attached to the lower end of the individual heater 25. The heating jig 81 has a predetermined contact surface received on the surface of the element 16. The heating jig 81 is made out of a block. The block is made of a metallic material having a high thermal conductivity, such as copper or aluminum. The heating jig 81 has contact surfaces having various areas to contact with the element 16, as describe later in detail. The heat of the heater 25 is transferred to the element 16 via the heating jig 81.

As depicted in FIG. 22, the heating jig 81 includes a first block 82 and a second block 83. The first and second blocks 82, 83 are formed in a prismatic shape. The first block 82 and the second block 83 are formed integral with each other at their side surfaces. The first block 82 stands upright along a first axis X1 perpendicular to an imaginary plane. The second block 83 extends along a second axis X2 parallel to the imaginary plane. The half of the first block 82 and the half of the second block 83 in combination define a prismatic shape extending along a third axis X3 perpendicular to the first axis X1 and the second axis X2. The first axis X1 the second axis X2 and the third axis X3 are set parallel to the y-axis, z-axis and x-axis of a three-dimensional coordinate system, respectively.

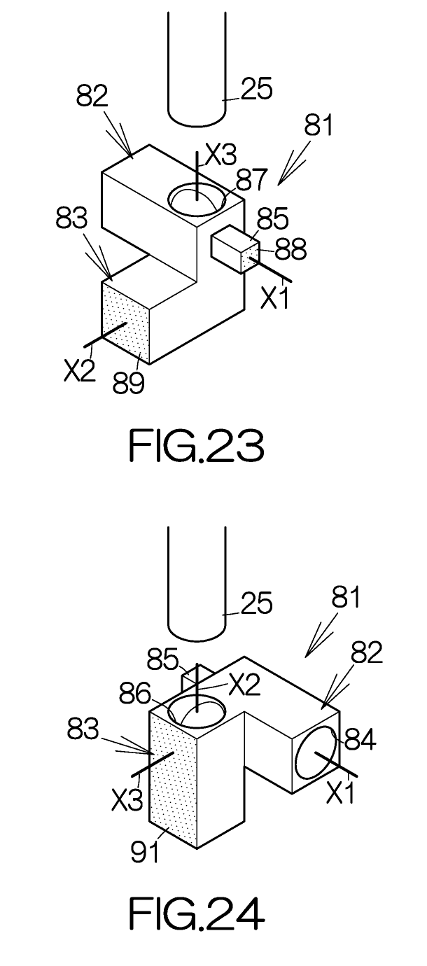

A first insertion hole 84 is formed in one end surface of the first block 82 to extend along the first axis X1. The first insertion hole 84 is a bottomed hole. A protrusion 85 is formed on the other end surface of the first block 82. The protrusion 85 is formed in the shape of a prism, for example. A second insertion hole 86 is formed in one end surface of the second block 83 to extend along the second axis X2. The second insertion hole 86 is a bottomed hole. Referring also to FIG. 23, a third insertion hole 87 is formed in the side surface of the first block 82 to extend along the third axis X3. The third insertion hole 87 is a bottomed hole. The third insertion hole 87 is connected to the first insertion hole 84 and the second insertion hole 86. The diameters of the first, second and third insertion holes 84, 86, 87 are set sufficiently large to accept insertion of the heater 25.

A first contact surface 88 is defined in the top surface of the protrusion 85. The first contact surface 88 intersects the first axis X1. Likewise, a second contact surface 89 is defined in the other end surface of the second block 83. The other end surface of the second block 83 is an end surface opposite to the end surface with the second insertion hole 86. The second contact surface 89 is set perpendicular to the second axis X2. Referring also to FIG. 24, a third contact surface 91 is defined in the side surface of the second block 83. The third contact surface 91 intersects the third axis X3. The areas of the first contact surface 88, the second contact surface 89 and the third contact surface 91 are different from one another. Here, the area of the second contact surface 89 may be set larger than the area of the first contact surface 88, while the area of the third contact surface 91 may be set larger than the area of the second contact surface 88.

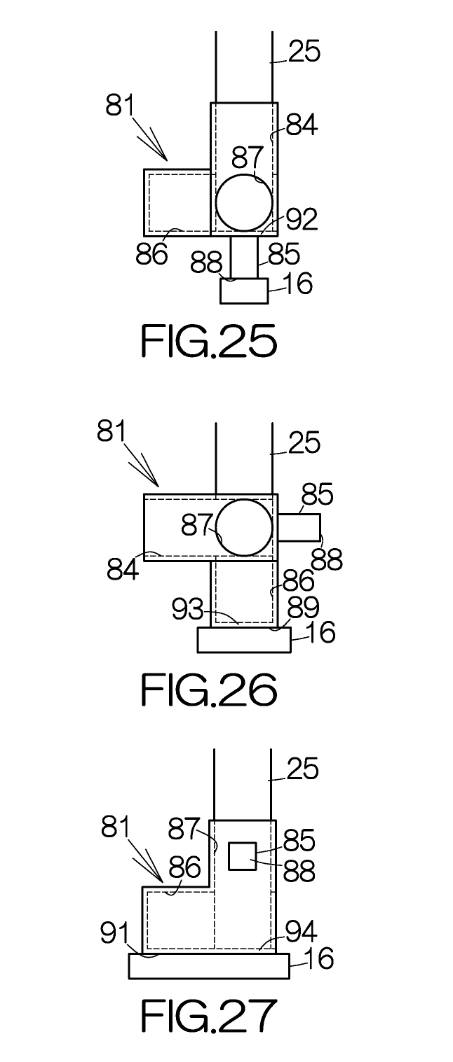

For the use of the heating jig 81, one contact surface, whose area is suitable to the area of the surface of the element 16, is selected from the first, second and third contact surfaces 88, 89, 91. As depicted in FIG. 25, if the area of the surface of the element 16 is smaller than the area of the lower end surface of the heater 25, for example, the first contact surface 88 is selected. In this case, the heater 25 is inserted in the first insertion hole 84. The lower end of the heater 25 is received on the bottom of the first insertion hole 84, namely a bottom wall 92 of the first block 82. For realizing an efficient heat transfer, the thickness of the bottom wall 92 of the first block 82 is reduced appropriately in view of the strength. The heating jig 81 is urged against the element 16. The heat of the heater 25 is transferred to the element 16 via the first contact surface 88 of the protrusion 85.

If the area of the surface of the element 16 is larger than that of the lower end surface of the heater 25, for example, the second contact surface 89 is selected, as depicted in FIG. 26. In this case, the heater 25 is inserted in the second insertion hole 86. The thickness of a bottom wall 93 of the second block 83 is reduced in the same manner as described above. The heat of the heater 25 is transferred to the element 16 via the second contact surface 89. If the area of the surface of the element 16 is much larger than that of the lower end surface of the heater 25, the third contact surface 91 is selected, as depicted in FIG. 27. The heater 25 is inserted in the third insertion hole 87. The thickness of a side wall 94 of the second block 83 is reduced in the same manner as described above. The heat of the heater 25 is transferred to the element 16 via the third contact surface 91.

In the heating jig 81, since the areas of the contact surfaces 88, 89, 91 are different from one another, the heater 25 may be inserted in one of the insertion holes 84, 86, 87 in accordance with the size of the element 16. The contact surfaces 88, 89, 91 can contact with the surface of the element 16 with efficiency. The heat of the heater 25 is transferred to the element 16 with efficiency irrespective of the area of the lower end surface of the heater 25. The heater 25 serves to heat the elements 16 of various sizes with efficiency. The monitored temperature test apparatus 21, namely the monitored burn-in test apparatus 11, is usable for monitored burn-in tests for the elements 16 of various sizes. The versatility of the monitored burn-in test apparatus 11 is improved.

It should be noted that a thermally-conductive body such as a thermally-conductive grease or compound may be utilized to fill a space inside the insertion holes 84, 86, 87 outside the outer peripheral surface of the heater 25, for example. The thermally-conductive body serves to reduce thermal resistance between the heater 25 and the heating jig 81. As a result, the heat of the heater 25 can be transferred to the heating jig 81, namely the element 16, with a higher efficiency.

All examples and conditional language recited herein are intended for pedagogical purposes to aid the reader in understanding the invention and the concept contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A monitored burn-in test method comprising:
subjecting an element set, including elements, to a writing process for writing data into each of the elements, the elements requiring a refresh process;
subjecting the element set to the refresh process after the writing process; and
interrupting the refresh process for a selected one or ones of the elements, when instructions for readout of data are supplied to the selected one or ones during the refresh process, and subjecting the selected one or ones to a readout process in accordance with the instructions.

2. The monitored burn-in test method according to claim 1, further comprising:
resuming the refresh process for the selected one or ones which has been subjected to the readout process;
subjecting the element set to a burn-in process; and
interrupting the refresh process for a further selected one or ones of the elements for a readout process for reading out data from the further selected one or ones after the burn-in process.

3. The monitored burn-in test method according to claim 1, further comprising comparing the data read from the selected one or ones with the data written into the elements.

4. A monitored burn-in test apparatus comprising:
a writing process means for subjecting an element set, including elements mounted on a burn-in board, to a writing process, the elements requiring a refresh process;
a refresh process means for subjecting the element set to the refresh process after the writing process by the writing means; and
a readout process means for interrupting the refresh process by the refresh process means for a selected one or ones of the elements, when instructions for readout of data are supplied to the selected one or ones during the refresh process by the refresh process means, and subjecting the selected one or ones to a readout process in accordance with the instructions.

5. A monitored temperature test apparatus comprising:
heaters respectively contacting with elements arranged in plural rows and plural columns;
temperature sensors respectively contacting with the elements;
a first temperature measuring unit connected to a first temperature sensor set including temperature sensors selected from the temperature sensors of each row, the first temperature measuring unit detecting temperatures of the elements corresponding to the temperature sensors in the first temperature sensor set;
a second temperature measuring unit connected to a second temperature sensor set including temperature sensors selected from the temperature sensors of each column other than the first temperature sensor set, the second temperature measuring units detecting temperatures of the elements corresponding to the temperature sensors in the second temperature sensor set; and
a controller circuit configured to adjust temperature of one or ones of the heaters contacting with a selected one or ones of the elements when the first and second temperature measuring units detect temperature of the selected one or ones of the elements outside a predetermined temperature range.

6. The monitored temperature test apparatus according to claim 5, wherein a number of the temperature sensors in the first temperature sensor set is set equal for each row.

7. The monitored temperature test apparatus according to claim 6, wherein a number of the temperature sensors in the first temperature sensor set is set equal for each column.

8. The monitored temperature test apparatus according to claim 5, wherein a number of the temperature sensors in the first temperature sensor set is set equal to a number of the temperature sensors in the second temperature sensor set in each row.

9. The monitored temperature test apparatus according to claim 8, wherein a number of the temperature sensors in the first temperature sensor set is set equal to a number of the temperature sensors in the second temperature sensor set in each column.

10. The monitored temperature test apparatus according to claim 5, further comprising:
a board supporting the temperature sensors and the first and second temperature measuring units;
first wiring patterns formed on the board, the first wiring patterns respectively connecting the temperature sensors in the first temperature sensor set to the first temperature measuring unit in parallel; and
second wiring pattern formed on the board, the second wiring patterns respectively connecting the temperature sensors in the second temperature sensor set to the second temperature measuring unit in parallel.

11. A method of adjusting temperature for a monitored temperature test apparatus, comprising:
adjusting temperatures of heaters respectively contacting with elements arranged in plural rows and plural columns to heat the elements to a predetermined temperature;
causing a first temperature measuring unit to detect temperatures through a first temperature sensor set including a selected one or ones of temperature sensors respectively contacting with the elements, the selected one or ones contacting a selected one or ones of the elements in each row, respectively, the first temperature measuring unit individually connected to the selected one or ones of the temperature sensors in parallel;
causing a second temperature measuring unit to detect temperatures through a second temperature sensor set including a further selected one or ones of the temperature sensors other than the first temperature sensor set, the further selected one or ones contacting a further selected one or ones of the elements in each column, respectively, the second temperature measuring unit individually connected to the further selected one or ones of the temperature sensors in parallel; and
adjusting temperature of one or ones of the heaters contacting with a still further selected one or ones of the elements when the first and second temperature measuring units detect temperature of the still further selected one or ones of the elements outside a predetermined temperature range.
